(19) United States
(12) Patent Application Publication
(10) Pub. No.: US 2025/0268083 A1
(43) Pub. Date: Aug. 21, 2025

(54) DISPLAY DEVICE

(71) Applicant: SAMSUNG DISPLAY CO., LTD., YONGIN-SI (KR)

(72) Inventors: SEUNGYEON JEONG, Yongin-si (KR); OHJEONG KWON, Yongin-si (KR); HYEOJI KANG, Yongin-si (KR); HYEBEOM SHIN, Yongin-si (KR); HONGYEON LEE, Yongin-si (KR)

(21) Appl. No.: 18/926,522

(22) Filed: Oct. 25, 2024

(30) Foreign Application Priority Data
Feb. 16, 2024 (KR) 10-2024-0022970

(51) Int. Cl. H10K 59/80; H10K 59/122; H10K 59/38; H10K 59/40; H10K 59/65

(52) U.S. Cl. CPC H10K 59/8792; H10K 59/122; H10K 59/38; H10K 59/8723; H10K 59/877; H10K 59/40; H10K 59/65

(57) ABSTRACT

A display device includes a first light emitting area that emits first light, a second light emitting area that emits second light, and a third light emitting area that emits third light respectively defined on a substrate, an input sensing layer disposed on the substrate and including a first input insulating layer, the first input insulating layer overlapping the first light emitting area and the second light emitting area in a plan view and including scattering particles, and a color filter layer disposed on the input sensing layer.

### CROSS-REFERENCE TO RELATED APPLICATION(S)

This application claims priority under 35 U.S.C. § 119 to Korean Patent Application No. 10-2024-0022970, filed on Feb. 16, 2024, in the Korean Intellectual Property Office (KIPO), the entire disclosure of which is incorporated by reference herein.

### TECHNICAL FIELD

The present disclosure relates to a display device.

### DISCUSSION OF RELATED ART

Electrodes, metal lines, or the like of a display panel included in a display device may reflect various lights. When light is generated from a light emitting element of the display device, some of the generated light may be reflected from the electrodes, the metal lines, or the like of the display panel. In addition, when an external light source exists, external light introduced into inside of the display device from outside may be reflected from the electrodes, the metal lines, or the like of the display panel. When such reflected light is visually recognized from the outside, it may affect display quality of the display device. For example, a user may visually recognize a color band due to reflection from the electrodes, the metal lines, or the like of the display panel.

### SUMMARY

Embodiments of the present disclosure provide a display device with enhanced display quality.

A display device according to an embodiment of the present disclosure includes a first light emitting area that emits first light, a second light emitting area that emits second light, and a third light emitting area that emits third light, an input sensing layer disposed on the substrate and including a first input insulating layer, the first input insulating layer overlapping the first light emitting area and the second light emitting area in a plan view and including scattering particles, and a color filter layer disposed on the input sensing layer.

In an embodiment of the present disclosure, the first input insulating layer may not overlap the third light emitting area in a plan view.

In an embodiment of the present disclosure, the first light may be light in a red wavelength band, the second light may be light in a green wavelength band, and the third light may be light in a blue wavelength band.

In an embodiment of the present disclosure, the first input insulating layer may include an organic material.

In an embodiment of the present disclosure, an average diameter of the scattering particles may be greater than or equal to about 50 nm and smaller than or equal to about 500 nm.

In an embodiment of the present disclosure, a content of the scattering particles included in the first input insulating layer may be greater than 0 wt % and less than or equal to about 10 wt % based on a total weight of the first input insulating layer.

In an embodiment of the present disclosure, a thickness of the first input insulating layer may be greater than or equal to about 1.0 μm and smaller than or equal to about 1.8 μm.

In an embodiment of the present disclosure, the input sensing layer may further include a second input insulating layer disposed on the first input insulating layer and covering the first input insulating layer.

In an embodiment of the present disclosure, the second input insulating layer may continuously extend in the first light emitting area, the second light emitting area, and the third light emitting area.

In an embodiment of the present disclosure, the color filter layer may include a first color filter overlapping the first light emitting area in a plan view, a second color filter overlapping the second light emitting area in a plan view, and a third color filter overlapping the third light emitting area in a plan view.

In an embodiment of the present disclosure, the color filter layer may further include a light blocking portion disposed between the first color filter, the second color filter, and the third color filter.

In an embodiment of the present disclosure, a haze of the first input insulating layer may be greater than or equal to about 10% and less than or equal to about 50%.

In an embodiment of the present disclosure, the display device may further include a pixel defining layer disposed between the substrate and the input sensing layer, and a spacer disposed on the pixel defining layer.

In an embodiment of the present disclosure, the spacer may include the scattering particles.

In an embodiment of the present disclosure, a content of the scattering particles included in the spacer may be greater than or equal to about 5 wt % and less than or equal to about 50 wt % based on a total weight of the spacer.

In an embodiment of the present disclosure, the display device may further include a light emitting layer disposed between the substrate and the input sensing layer. The light emitting layer may include a first light emitting layer overlapping the first light emitting area in a plan view and emitting the first light, a second light emitting layer overlapping the second light emitting area in a plan view and emitting the second light, and a third light emitting layer overlapping the third light emitting area and emitting the third light.

A display device according to an embodiment of the present disclosure includes a light emitting area and a non-light emitting area surrounding the light emitting area respectively defined on a substrate, a pixel defining layer disposed on the substrate and overlapping the non-light emitting area in a plan view, a spacer disposed on the pixel defining layer, overlapping the non-light emitting area in a plan view, and including scattering particles in a content of greater than or equal to about 5 wt % and less than or equal to about 50 wt % based on a total weight of the spacer, and a color filter layer disposed on the spacer.

In an embodiment of the present disclosure, an average diameter of the scattering particles may be greater than or equal to about 50 nm and smaller than or equal to about 500 nm.

In an embodiment of the present disclosure, the display device may further include an input sensing layer disposed between the spacer and the color filter layer.

In an embodiment of the present disclosure, the light emitting area may include a first light emitting area that emits first light, a second light emitting area that emits second light, and a third light emitting area that emits third light, and the color filter layer may include a first color filter overlapping the first light emitting area in a plan view, a second color filter overlapping the second light emitting area in a plan view, and a third color filter overlapping the third light emitting area in a plan view.

In an embodiment of the present disclosure, the color filter layer may further include a light blocking portion overlapping the non-light emitting area in a plan view.

In an embodiment of the present disclosure, the first light may be light in a red wavelength band, the second light may be light in a green wavelength band, and the third light may be light in a blue wavelength band.

In an embodiment of the present disclosure, the display device may further include a light emitting layer disposed between the substrate and the color filter layer. The light emitting layer may include a first light emitting layer overlapping the first light emitting area in a plan view and emitting the first light, a second light emitting layer overlapping the second light emitting area in a plan view and emitting the second light, and a third light emitting layer overlapping the third light emitting area in a plan view and emitting the third light.

A display device according to an embodiment of the present disclosure includes a display panel, an input sensing layer, and a color filter layer sequentially disposed on a substrate. The display panel may include a first light emitting area that emits red light, a second light emitting area that emits green light, and a third light emitting area that emits blue light. The input sensing layer may include a first conductive layer, a first input insulating layer disposed on and covering the first conductive layer, a second conductive layer disposed on the first input insulating layer, and a second input insulating layer disposed on and covering the second conductive layer and the first input insulating layer. The first input insulating layer may include scattering particles and may not overlap the third light emitting area in a plan view

In a display device according to an embodiment of the present disclosure, an input sensing layer may include an input insulating layer including scattering particles. In a plan view, the input insulating layer may overlap a first light emitting area that emits first light and a second light emitting area that emits second light, and may not overlap a third light emitting area that emits third light. Accordingly, a color band phenomenon due to reflection of external light may be prevented or minimized, and a decrease in light extraction efficiency of the display device may be minimized, thereby enhancing display quality of the display device.

In addition, in a display device according to an embodiment of the present disclosure, a spacer may be disposed on a pixel defining layer, and may include scattering particles. Accordingly, a color band phenomenon due to reflection of external light may be prevented or minimized, and a decrease in light extraction efficiency of the display device may be minimized, thereby enhancing display quality of the display device.

### BRIEF DESCRIPTION OF THE DRAWINGS

Embodiments of the present disclosure will be more clearly understood from the following detailed description taken in conjunction with the accompanying drawings in which:

FIG. 1 is a plan view illustrating a display device according to an embodiment of the present disclosure;

FIG. 2 is an enlarged plan view of a portion of a display area of the display device of FIG. 1;

FIG. 3 is an example of a cross-sectional view taken along line I-I′ of FIG. 2;

FIG. 4 is a cross-sectional view illustrating a circuit layer included in the display device of FIG. 3;

FIG. 5 is a cross-sectional view illustrating a scattering particle included in the display device of FIG. 3;

FIG. 6 is an example of a cross-sectional view taken along line I-I′ of FIG. 2;

FIG. 7 is a cross-sectional view illustrating a display device according to an embodiment of the present disclosure; and

FIG. 8 is a cross-sectional view illustrating a display device according to an embodiment of the present disclosure.

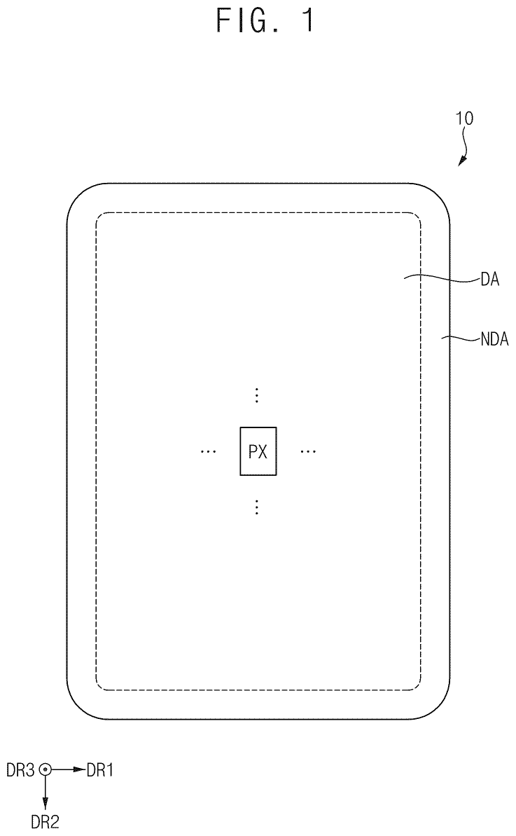

Since the drawings in FIGS. 1-8 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

FIG. 1 is a plan view illustrating a display device according to an embodiment of the present disclosure.

Referring to FIG. 1, a display device 10 may include a display area DA and a non-display area NDA.

The display area DA may be an area that displays an image. A plurality of pixels PX may be disposed in the display area DA. The plurality of pixels PX may be arranged in a matrix form along a first direction DR1 and a second direction DR2 intersecting the first direction DR1, but the present disclosure is not limited thereto. For example, the plurality of pixels PX may be arranged in a pentile matrix shape, or a diamond shape. For example, the first direction DR1 may be perpendicular to the second direction DR2. Each of the plurality of pixels PX may emit light. As each of the plurality of pixels PX emits light, the display area DA may display an image in a third direction DR3 intersecting each of the first direction DR1 and the second direction DR2. For example, the third direction DR3 may be perpendicular to each the first direction DR1 and the second direction DR2. The image includes not only a moving image, but also a still image.

Lines connected to the plurality of pixels PX may be further disposed in the display area DA. For example, the lines may include, for example, a data signal line, a gate signal line, a power line, or the like.

The non-display area NDA may be an area that does not display an image. The non-display area NDA may be disposed around the display area DA. For example, the non-display area NDA may surround the display area DA in a plan view. However, FIG. 1 merely illustrates an example, and the non-display area NDA may be arranged adjacent to only one side of the display area DA, or may not be provided.

Drivers that drive the plurality of pixels PX may be disposed in the non-display area NDA. For example, the drivers may include a data driver, a gate driver, a power voltage generator, a timing controller, or the like. For example, the driver may provide a data signal, a gate signal, an emission control signal, a gate initialization signal, an initialization voltage, a power supply voltage, or the like to the display area DA. The plurality of pixels PX may emit light based on signals received from the drivers.

The display device 10 may detect an external input applied from outside. The external input may include various types of inputs provided from the outside of the display device 10. For example, the external input may include a contact by a part of a body such as a user's hand, as well as an external input applied close to the display device 10 or adjacent to the display device 10 by a predetermined distance (e.g., hovering). In addition, the external input may have various forms such, for example, as force, pressure, temperature, light, or the like. For example, the display device 10 may obtain coordinate information according to an external input, for example, a touch event.

The display device 10 may detect a user's biometric information applied from the outside. The biometric information can be a photo of the user's face, a record of the user's voice, or an image of the user's fingerprint, but the present disclosure is not limited thereto. A biometric information detection area that detects the user's biometric information may be provided in the display area DA of the display device 10. The biometric information detection area may be provided in an entire area of the display area DA, or may be provided in a partial area of the display area DA.

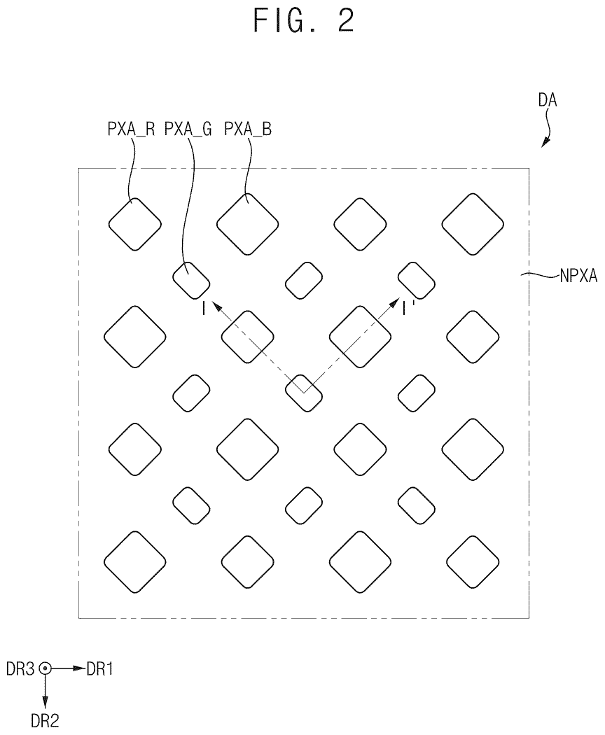

FIG. 2 is an enlarged plan view of a portion of a display area of the display device of FIG. 1.

Referring to FIGS. 1 and 2, the display area DA of the display device 10 may include a first light emitting area PXA_R, a second light emitting area PXA_G, a third light emitting area PXA_B, and a non-light emitting area NPXA. Each of the first light emitting area PXA_R, the second light emitting area PXA_G, and the third light emitting area PXA_B may emit light. For example, each of the first light emitting area PXA_R, the second light emitting area PXA_G, and the third light emitting area PXA_B may be defined on the substrate SUB as an area in which light emitted from a light emitting element is emitted to the outside of the display device 10. As each of the first light emitting area PXA_R, the second light emitting area PXA_G, and the third light emitting area PXA_B emits light, the display area DA may display an image. The first, second, and third light emitting areas PXA_R, PXA_G, and PXA_B may correspond to the plurality of pixels PX, respectively.

In an embodiment of the present disclosure, the first light emitting area PXA_R, the second light emitting area PXA_G, and the third light emitting area PXA_B may emit light in different wavelength bands. The first light emitting area PXA_R may emit first light, the second light emitting area PXA_G may emit second light, and the third light emitting area PXA_B may emit third light. For example, the first light may be light in a red wavelength band which may be in a range from about 620 nanometers (nm) to about 750 nm, the second light may be light in a green wavelength band which may be in a range from about 495 nm to about 570 nm, and the third light may be light in a blue wavelength band which may be in a range from about 450 nm to about 495 nm, but the present disclosure is not limited thereto. “About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In an embodiment of the present disclosure, the first light emitting area PXA_R, the second light emitting area PXA_G, and the third light emitting area PXA_B may emit light in the same wavelength band. In an embodiment of the present disclosure, at least one of the first light emitting area PXA_R, the second light emitting area PXA_G, and the third light emitting area PXA_B may emit light in a different wavelength band.

In an embodiment of the present disclosure, the first light emitting area PXA_R and the third light emitting area PXA_B may be disposed in the same row and the same column, and may be alternately arranged along the first direction DR1 and the second direction DR2. The second light emitting area PXA_G may be disposed in different rows and different columns from the first light emitting area PXA_R and the third light emitting area PXA_B, and may be arranged along the first direction DR1 and the second direction DR2. However, the present disclosure is not limited thereto, and an arrangement of the first, second, and third light emitting areas PXA_R, PXA_G, and PXA_B may be variously modified.

In an embodiment of the present disclosure, the first light emitting rea PXA_R may have an area larger than that of the second light emitting area PXA_G in a plan view. The third light emitting area PXA_B may have an area larger than or the same as that of the first light emitting area PXA_R in a plan view. However, the present disclosure is not limited thereto, and an area of each of the first, second, and third light emitting areas PXA_R, PXA_G, and PXA_B may be variously modified. In an embodiment of the present disclosure, the shape of the first, second, and third light emitting areas PXA_R, PXA_G, and PXA_B may be generally, for example, an octagon, a square or a diamond with or without rounded corners. It is, however, to be understood that the present disclosure is not limited thereto. For example, the shape of the first, second, and third light emitting areas PXA_R, PXA_G, and PXA_B may be a circle, or other polygons with or without rounded corners. The first, second, and third light emitting areas PXA_R, PXA_G, and PXA_B may have different shapes and/or sizes from each other.

The non-light emitting area NPXA may be an area that does not emit light. The non-light emitting area NPXA may surround each of the first, second, and third light emitting areas PXA_R, PXA_G, and PXA_B. For example, the non-light emitting area NPXA may partition the first, second, and third light emitting areas PXA_R, PXA_G, and PXA_B.

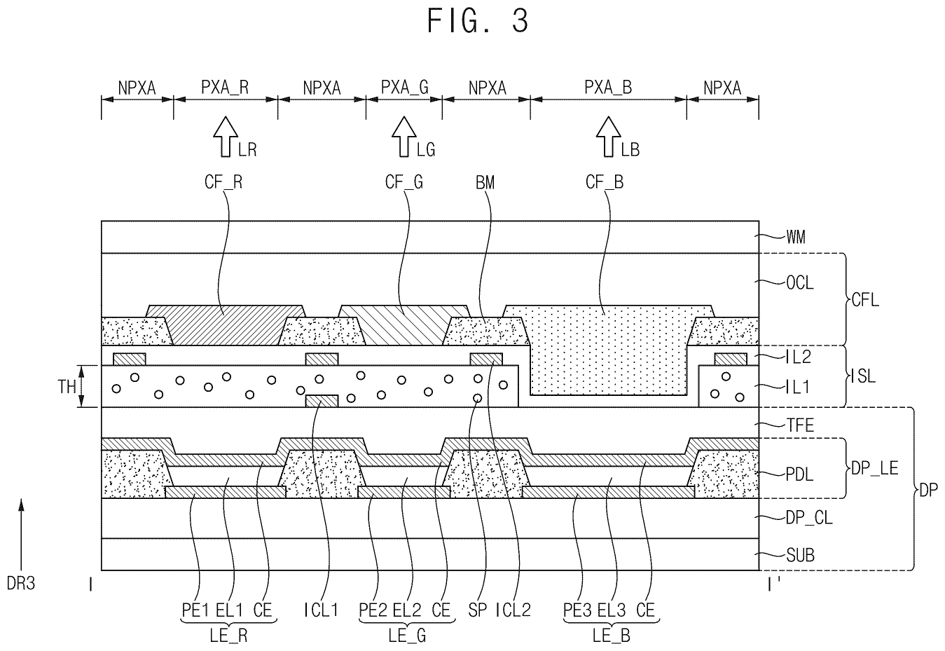

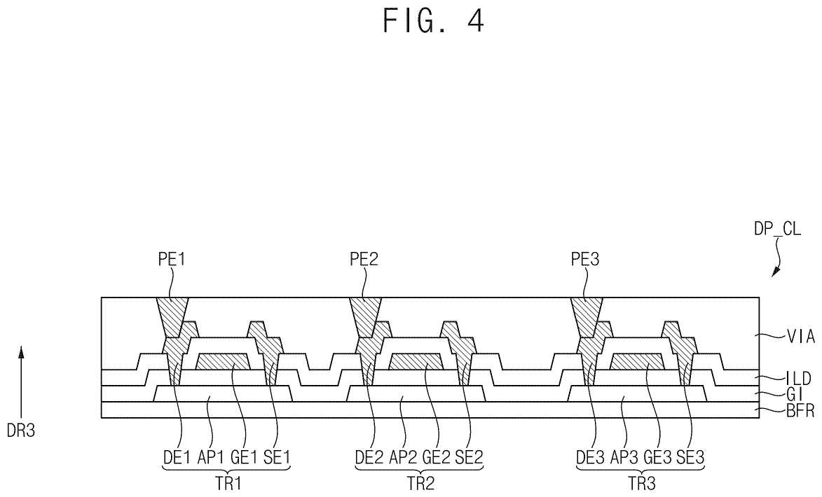

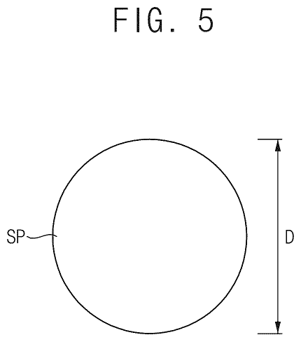

FIG. 3 is an example of a cross-sectional view taken along line I-I′ of FIG. 2. FIG. 4 is a cross-sectional view illustrating a circuit layer included in the display device of FIG. 3. FIG. 5 is a cross-sectional view illustrating a scattering particle included in the display device of FIG. 3.

Referring to FIGS. 3, 4, and 5, the display device 10 may include a display panel DP, an input sensing layer ISL, a color filter layer CFL, and a window WM. The display panel DP may include a substrate SUB, a circuit layer DP_CL, an element layer DP_LE, and an encapsulation layer TFE.

The substrate SUB may include a transparent material or an opaque material. Examples of the material that may be used as the substrate SUB may include, for example, polyimide, quartz, glass, or the like. These may be used alone or in combination with each other. According to an embodiment of the present disclosure, the substrate SUB may include a flexible material. The flexible material may refer to a substrate that is flexible, and is easily bendable, foldable, or rollable. The substrate SUB including such a flexible material may include, for example, ultrathin type glass, or plastic.

The circuit layer DP_CL may be disposed on the substrate SUB. The circuit layer DP_CL may include a buffer layer BFR, a first transistor TR1, a second transistor TR2, a third transistor TR3, a gate insulating layer GI, an interlayer insulating layer ILD, and a via insulating layer VIA. The circuit layer DP-CL may include driving circuits of the pixels PX. The driving circuits of the pixels PX may include transistors, such as the first transistor TR1, the second transistor TR2, and the third transistor TR3, and capacitors.

Here, the first transistor TR1 may include a first active pattern AP1, a first gate electrode GE1, a first source electrode SE1, and a first drain electrode DE1, the second transistor TR2 may include a second active pattern AP2, a second gate electrode GE2, a second source electrode SE2, and a second drain electrode DE2, and the third transistor TR3 may include a third active pattern AP3, a third gate electrode GE3, a third source electrode SE3, and a third drain electrode DE3.

The buffer layer BFR may be disposed on the substrate SUB. The buffer layer BFR may prevent metal atoms or impurities from being diffused from the substrate SUB to the first transistor TR1, the second transistor TR2, and the third transistor TR3. In addition, when a surface of the substrate SUB is not uniform, the buffer layer BFR may enhance a flatness of the surface of the substrate SUB. In an embodiment of the present disclosure, the buffer layer BFR may adjust a heat transfer rate during a crystallization process for forming the first, second, and third active patterns AP1, AP2, and AP3, so that the first, second, and third active patterns AP1, AP2, and AP3 may be uniformly formed. The buffer layer BFR may include an inorganic material such as, for example, silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The first, second, and third active patterns AP1, AP2, and AP3 may be disposed on the buffer layer BFR. Each of the first, second, and third active patterns AP1, AP2, and AP3 may include a source area, a drain area, and a channel area between the source area and the drain area. Each of the first, second, and third active patterns AP1, AP2, and AP3 may include a silicon (Si) semiconductor material or an oxide semiconductor material. Examples of the silicon (Si) semiconductor material may include, for example, amorphous silicon (a-Si), polycrystalline silicon (pc-Si), or the like. Examples of the oxide semiconductor material may include, for example, indium gallium zinc oxide (IGZO), indium tin zinc oxide (ITZO), or the like. These may be used alone or in combination with each other.

The gate insulating layer GI may be disposed on the buffer layer BFR and the first, second, and third active patterns AP1, AP2, and AP3. For example, the gate insulating layer GI may cover the first, second, and third active patterns AP1, AP2, and AP3. The gate insulating layer GI may include an inorganic material such as, for example, aluminum oxide (Al₂O₃), titanium oxide (TiO₂), tantalum oxide (Ta₂O₅), hafnium oxide (HfO₂), lanthanum oxide (La₂O₃), zirconium oxide (ZrO₂), silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The first, second, and third gate electrodes GE1, GE2, and GE3 may be disposed on the gate insulating layer GI. The first, second, and third gate electrodes GE1, GE2, and GE3 may overlap the channel area of the first, second, and third active patterns AP1, AP2, and AP3, respectively, in a plan view. The first, second, and third active patterns AP1, AP2, and AP3 may be electrically insulated from the first, second, and third gate electrodes GE1, GE2, and GE3 by the gate insulating layer GI. Each of the first, second, and third gate electrodes GE1, GE2, and GE3 may include, for example, a metal, an alloy, a conductive metal oxide, a conductive metal nitride, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide (ITO), indium zinc oxide (IZO), zinc oxide (ZnO), indium tin zinc oxide (ITZO), or the like. Examples of the conductive metal nitride may include aluminum nitride (AlNₓ), tungsten nitride (WNₓ), chromium nitride (CrNₓ), or the like. These may be used alone or in combination with each other. Additionally or alternatively, the first, second, and third gate electrodes GE1, GE2, and GE3 may include a metal nano-wire, a graphene, or a conductive polymer such as poly (3,4-ethylenedioxythiophene) (PEDOT).

The interlayer insulating layer ILD may be disposed on the gate insulating layer GI and the first, second, and third gate electrodes GE1, GE2, and GE3. The interlayer insulating layer ILD may cover the first, second, and third gate electrodes GE1, GE2, and GE3. In an embodiment of the present disclosure, the interlayer insulating layer ILD may be disposed over the whole of the display area DA and the non-display area NDA on the gate insulating layer GI. The interlayer insulating layer ILD may include an inorganic material such as, for example, silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The first, second, and third source electrodes SE1, SE2, and SE3 and the first, second, and third drain electrodes DE1, DE2, and DE3 may be disposed on the interlayer insulating layer ILD. Each of the first, second, and third source electrodes SE1, SE2, and SE3 and the first, second, and third drain electrodes DE1, DE2, and DE3 may include, for example, a metal, an alloy, a conductive metal oxide, a conductive metal nitride, or the like. These may be used alone or in combination with each other. In an embodiment of the present disclosure, each of the first, second, and third source electrodes SE1, SE2, and SE3 and the first, second, and third drain electrodes DE1, DE2, and DE3 may have a multilayer structure including a plurality of conductive layers. For example, each of the first, second, and third source electrodes SE1, SE2, and SE3 and the first, second, and third drain electrodes DE1, DE2, and DE3 may have a multilayer structure, for example, a tri-layer structure of Ti/Al/Ti, in which titanium (Ti), aluminum (Al), and titanium (Ti) are sequentially stacked.

The first, second, and third source electrodes SE1, SE2, and SE3 may be connected to the first, second, and third active patterns AP1, AP2, and AP3, respectively. For example, the first, second, and third source electrodes SE1, SE2, and SE3 may be in contact with the source areas of the first, second, and third active patterns AP1, AP2, and AP3, respectively. In addition, the first, second, and third drain electrodes DE1, DE2, and DE3 may be connected to the first, second, and third active patterns AP1, AP2, and AP3, respectively. For example, the first, second, and third drain electrodes DE1, DE2, and DE3 may be in contact with the drain areas of the first, second, and third active patterns AP1, AP2, and AP3, respectively.

The via insulating layer VIA may be disposed on the interlayer insulating layer ILD, the first, second, and third source electrodes SE1, SE2, and SE3, and the first, second, and third drain electrodes DE1, DE2, and DE3. The via insulating layer VIA may cover the first, second, and third source electrodes SE1, SE2, and SE3 and the first, second, and third drain electrodes

DE1, DE2, and DE3. In an embodiment of the present disclosure, the via insulating layer VIA may be disposed over the whole of the display area DA and the non-display area NDA on the interlayer insulating layer ILD. The via insulating layer VIA may protect the first transistor TR1, the second transistor TR2, and the third transistor TR3, and may provide a flat surface to upper portions of the first transistor TR1, the second transistor TR2, and the third transistor TR3. In addition, the via insulating layer VIA may also be used to cover and protect some wirings on the interlayer insulating layer ILD. The via insulating layer VIA may include an organic material such as, for example, a phenol resin, an acrylic resin, a polyimide resin, a polyamide resin, a siloxane resin, an epoxy resin, or the like. These may be used alone or in combination with each other.

The element layer DP_LE may be disposed on the circuit layer DP_CL. The element layer DP_LE may include a first light emitting element LE_R, a second light emitting element LE_G, a third light emitting element LE_B, and a pixel defining layer PDL.

Here, the first light emitting element LE_R may include a first pixel electrode PE1, a first light emitting layer EL1, and a common electrode CE, the second light emitting element LE_G may include a second pixel electrode PE2, a second light emitting layer EL2, and the common electrode CE, and the third light emitting element LE_B may include a third pixel electrode PE3, a third light emitting layer EL3, and the common electrode CE. The common electrode CE may be disposed to cover the pixel defining layer PDL and the first, second, and third light emitting layers EL1, EL2, and EL3.

The first, second, and third pixel electrodes PE1, PE2, and PE3 may be disposed on the circuit layer DP_CL. The first, second, and third pixel electrodes PE1, PE2, and PE3 may overlap the first, second, and third light emitting areas PXA_R, PXA_G, and PXA_B, respectively, in a plan view. The first, second, and third pixel electrodes PE1, PE2, and PE3 may be connected to the first, second, and third transistors TR1, TR2, and TR3, respectively. For example, the first, second, and third pixel electrodes PE1, PE2, and PE3 may be connected to the first, second, and third drain electrodes DE1, DE2, and DE3 or the first, second, and third source electrodes SE1, SE2, and SE3 through contact holes formed in the via insulating layer VIA, respectively. Each of the first, second, and third pixel electrodes PE1, PE2, and PE3 may include, for example, a metal, an alloy, a conductive metal oxide, a conductive metal nitride, a transparent conductive material, or the like. These may be used alone or in combination with each other. For example, each of the first, second, and third pixel electrodes PE1, PE2, and PE3 may include, for example, silver (Ag), indium tin oxide (ITO), and/or the like. These may be used alone or in combination with each other. In an embodiment of the present disclosure, each of the first, second, and third pixel electrodes PE1, PE2, and PE3 may have a multilayer structure including a plurality of conductive layers. For example, each of the first, second, and third pixel electrodes PE1, PE2, and PE3 may have a multilayer structure, for example, a tri-layer structure of ITO/Ag/ITO, in which indium tin oxide (ITO), silver (Ag), and indium tin oxide (ITO) are sequentially stacked.

The pixel defining layer PDL may be disposed on the circuit layer DP_CL. The pixel defining layer PDL may expose at least a portion of an upper surface of each of the first, second, and third pixel electrodes PE1, PE2, and PE3. For example, the pixel defining layer PDL may cover a side surface of each of the first, second, and third pixel electrodes PE1, PE2, and PE3, and may expose a central portion of each of the first, second, and third pixel electrodes PE1, PE2, and PE3. The pixel defining layer PDL may overlap the non-light emitting area NPXA in a plan view. The first, second, and third light emitting areas PXA_R, PXA_G, and PXA_B may be respectively defined corresponding to areas of the first, second, and third pixel electrodes PE1, PE2, and PE3 exposed by the pixel defining layer PDL on the substrate SUB. The non-light emitting area NPXA may be defined between the first, second, and third light emitting areas PXA_R, PXA_G, and PXA_B on the substrate SUB. For example, a light emitting area and the non-light emitting area NPXA surrounding the light emitting area may be respectively defined on the substrate SUB, in which the light emitting area may include the first, second, and third light emitting areas PXA_R, PXA_G, and PXA_B.

The pixel defining layer PDL may include an organic material such as, for example, a polyimide resin, an epoxy resin, a siloxane resin, or the like or an inorganic material such as, for example, silicon oxide (SiOₓ), silicon nitride (SiNₓ), silicon oxynitride (SiOₓN_{y}), or the like. These may be used alone or in combination with each other. In an embodiment of the present disclosure, the pixel defining layer PDL may include a light blocking material. In addition, the pixel defining layer PDL may implement a black pixel defining layer. The light blocking material may include carbon black, a black dye, a black pigment, a metal (e.g., nickel (Ni), aluminum (Al), molybdenum (Mo), and alloys thereof), a metal oxide (e.g., chromium oxide (CrO)), a metal nitride (e.g., chromium nitride (CrN)), or the like.

The first, second, and third light emitting layers EL1, EL2, and EL3 may be disposed on the first, second, and third pixel electrodes PE1, PE2, and PE3, respectively. The first, second, and third light emitting layers EL1, EL2, and EL3 may be disposed on the first, second, and third pixel electrodes PE1, PE2, and PE3 exposed by the pixel defining layer PDL, respectively. That is, the first, second, and third light emitting layers EL1, EL2, and EL3 may overlap the first, second, and third light emitting areas PXA_R, PXA_G, and PXA_B, respectively, in a plan view.

The first light emitting layer EL1 may emit the first light LR, and may include an organic material that emits the first light LR. The second light emitting layer EL2 may emit the second light LG, and may include an organic material that emits the second light LG. The third light emitting layer EL3 may emit the third light LB, and may include an organic material that emits the third light LB. For example, each of the first, second, and third light emitting layers EL1, EL2, and EL3 may include an organic light emitting layer including an organic material and an auxiliary layer. The auxiliary layer may include at least one of a hole injection layer, a hole transport layer, an electron transport layer, and an electron injection layer. In an embodiment of the present disclosure, each of the first, second, and third light emitting layers EL1, EL2, and EL3 may include one or both of an organic light emitting material and a quantum dot. For example, each of the first, second, and third light emitting layers EL1, EL2, and EL3 may include an organic material including a fluorescent or phosphorescent material that emits red, green, and blue light, respectively, or emits white light. The quantum dot is a particle having a crystal structure of several to tens of nanometers in size, and may include hundreds to thousands of atoms. The quantum dot may include a fluorescent material or a phosphorescent material, and may produce monochromatic red, green, and blue light. In addition, each of the first, second, and third light emitting layers EL1, EL2, and EL3 may include an inorganic light-emitting material, which may include crystalline semiconductors such as, for example, gallium nitride (GaN), indium phosphide (InP), etc.

The common electrode CE may be disposed on the pixel defining layer PDL and the first, second, and third light emitting layers EL1, EL2, and EL3. The common electrode CE may overlap the first, second, and third light emitting areas PXA_R, PXA_G, and PXA_B and the non-light emitting area NPXA in a plan view. For example, the common electrode CE may continuously extend in the first, second, and third light emitting areas PXA_R, PXA_G, and PXA_B and the non-light emitting area NPXA. The common electrode CE may include, for example, a metal, an alloy, a conductive metal oxide, a conductive metal nitride, a transparent conductive material, or the like. For example, the common electrode CE may include, for example, aluminum (Al), platinum (Pt), silver (Ag), magnesium (Mg), gold (Au), chromium (Cr), tungsten (W), titanium (Ti), or the like. For example, the common electrode CE may include a transparent conductive oxide (TCO) film such as, for example, an indium tin oxide (ITO) film, an indium zinc oxide (IZO) film, a zinc oxide (ZnO) film, or an indium oxide (In₂O₃) film. These may be used alone or in combination with each other.

The encapsulation layer TFE may be disposed on the common electrode CE, and may seal the element layer DP_LE. The encapsulation layer TFE may prevent impurities, moisture, outside air, or the like from penetrating into the first, second, and third light emitting elements LE_R, LE_G, and LE_B from the outside. The encapsulation layer TFE may include at least one inorganic encapsulation layer and at least one organic encapsulation layer. The inorganic encapsulation layer may protect the element layer DP_LE from moisture/oxygen, and the organic encapsulation layer may protect the element layer DP_LE from foreign matter such as dust particles. The organic encapsulation layer may provide a flat top surface, and may relieve stress between layers in contact with each other. The inorganic encapsulation layer may include, for example, silicon nitride (SiNₓ), silicon oxynitride (SiOₓN_{y}), silicon oxide (SiOₓ), titanium oxide (TiO₂), or aluminum oxide (Al₂O₃), but is not particularly limited thereto. The organic encapsulation layer may include, for example, an acryl-based compound or polymer, an epoxy-based compound or polymer, or the like.

The input sensing layer ISL may be disposed on the encapsulation layer TFE. For example, the input sensing layer ISL may be directly disposed on the encapsulation layer TFE. The input sensing layer ISL may sense the external input applied from the outside. The input sensing layer ISL may include a first conductive layer ICL1, a first input insulating layer IL1, a second conductive layer ICL2, and a second input insulating layer IL2.

The first conductive layer ICL1 may be disposed on the encapsulation layer TFE. The first conductive layer ICL1 may overlap the non-light emitting area NPXA in a plan view. The first conductive layer ICL1 may have a single layer structure or a multi-layer structure, and may include a plurality of conductive patterns. The first conductive layer ICL1 may include, for example, a metal, an alloy, a transparent conductive material, or the like. The first conductive layer ICL1 may include, for example, molybdenum (Mo), silver (Ag), titanium (Ti), copper (Cu), aluminum (Al), or an alloy thereof. The transparent conductive material for the first conductive layer ICL1 may include a transparent conductive oxide such as, for example, indium tin oxide (ITO), indium zinc oxide (IZO), zinc oxide (ZnO), indium zinc tin oxide (IZTO), or the like. These may be used alone or in combination with each other.

The first input insulating layer IL1 may be disposed on the first conductive layer ICL1. The first input insulating layer IL1 may cover the first conductive layer ICL1. In an embodiment of the present disclosure, in a plan view, the first input insulating layer IL1 may overlap the first light emitting area PXA_R and the second light emitting area PXA_G, and may not overlap the third light emitting area PXA_B. For example, in a plan view, the first input insulating layer IL1 may overlap the first and second light emitting areas PXA_R and PXA_G that emit light in a relatively long wavelength band, and may not overlap the third light emitting area PXA_B that emits light in a relatively short wavelength band. In addition, the first input insulating layer IL1 may overlap the non-light emitting area NPXA in a plan view.

The first input insulating layer IL1 may include an organic material such as, for example, an acrylic resin, a polyimide resin, or the like. The first input insulating layer IL1 may be formed not to overlap the third light emitting area PXA_B in a plan view through a photolithography process. The first input insulating layer IL1 having a relatively thick thickness is required to be formed to cover the first conductive layer ICL1. For example, a thickness TH of the first input insulating layer IL1 may be greater than or equal to about 1.0 micrometers (μm) and smaller than or equal to about 1.8 μm, but the present disclosure is not limited thereto. The first input insulating layer IL1 may provide a flat top surface on the encapsulation layer TFE.

In an embodiment of the present disclosure, the first input insulating layer IL1 may include scattering particles SP. The scattering particles SP may be dispersed and positioned within the first input insulating layer IL1. For example, the scattering particles SP may include, for example, titanium oxide (TiO₂), zinc oxide (ZnO), zirconium oxide (ZrO₂), aluminum oxide (Al₂O₃), cerium oxide (CeO₂), silicon oxide (SiO₂), or the like. The scattering particles SP may scatter light that is reflected from a lower component and travels to the outside, thereby preventing a color band due to reflection from being visually recognized or minimizing a degree to which it is visually recognized. In addition, the scattering particles SP may be disposed not to overlap the third light emitting area PXA_B that emits the third light LB in a plan view, thereby minimizing a decrease in light extraction efficiency of the display device 10. For example, the light extraction efficiency of the blue pixel PX will not be reduced or be minimally reduced, when the scattering particles SP are located in the first and second light emitting areas PXA_R and PXA_G corresponding to the red pixel PX and green pixel PX, but not located in the third light emitting area PXA_B corresponding to the blue pixel PX. Accordingly, display quality of the display device 10 may be enhanced.

The scattering particle SP may be, for example, spherical, elliptical, or amorphous. In an embodiment of the present disclosure, an average diameter of the scattering particles SP may be greater than or equal to about 50 nanometers (nm) and smaller than or equal to about 500 nm. For example, the average diameter of the scattering particles SP may be an arithmetic average of a cross-sectional diameter D of each of a plurality of scattering particles SP (see FIG. 5). If the average diameter of the scattering particles SP is smaller than about 50 nm, light extraction efficiency of the display device 10 may be relatively reduced, and if the average diameter of the scattering particles SP is greater than about 500 nm, film properties of the first input insulating layer IL1 may be relatively degraded.

In an embodiment of the present disclosure, a content of the scattering particles SP included in the first input insulating layer IL1 may be greater than or equal to 0 wt % and less than or equal to about 10 wt % based on a total weight of the first input insulating layer IL1. For example, a content of the scattering particles SP included in the first input insulating layer IL1 may be greater than 0 wt %, but not greater than about 10 wt %. If the content of the scattering particles SP is greater than about 10 wt %, it may be relatively difficult to manufacture the first input insulating layer IL1. A haze of the first input insulating layer IL1 may be greater than or equal to about 10% and less than or equal to about 50%. Since the first input insulating layer IL1 includes the scattering particles SP of greater than 0 wt % and about 10 wt % or less so that the haze of the first input insulating layer IL1 is maintained at about 10% or more and about 50% or less, a decrease in light extraction efficiency of the display device 10 may be minimized.

The second conductive layer ICL2 may be disposed on the first input insulating layer IL1. For example, the first input insulating layer IL1 including the scattering particles SP may be disposed between the first conductive layer ICL1 and the second conductive layer ICL2 to scatter light that is reflected from a lower component. The second conductive layer ICL2 may overlap the non-light emitting area NPXA in a plan view. The second conductive layer ICL2 may have a single layer structure or a multi-layer structure, and may include a plurality of conductive patterns. Some of the plurality of conductive patterns of the second conductive layer ICL2 may be connected to the first conductive layer ICL1. The second conductive layer ICL2 may include, for example, a metal, an alloy, a transparent conductive material, or the like. In an embodiment of the present disclosure, the second conductive layer ICL2 may include, for example, molybdenum (Mo), silver (Ag), titanium (Ti), copper (Cu), aluminum (Al), or an alloy thereof. In an embodiment of the present disclosure, the transparent conductive material for the second conductive layer ICL2 may include a transparent conductive oxide such as, for example, indium tin oxide (ITO), indium zinc oxide (IZO), zinc oxide (ZnO), indium zinc tin oxide (IZTO), or the like. These may be used alone or in combination with each other.

The second input insulating layer IL2 may be disposed on the first input insulating layer IL1 and the second conductive layer ICL2. The second input insulating layer IL2 may cover the first input insulating layer IL1 and the second conductive layer ICL2. The second input insulating layer IL2 may prevent the second conductive layer ICL2 from contacting the color filter layer CFL. Accordingly, a material (e.g., organic layer) that forms the color filter layer CFL may be prevented from damaging the second conductive layer ICL2. The second input insulating layer IL2 may overlap the first, second, and third light emitting areas PXA_R, PXA_G, and PXA_B and the non-light emitting area NPXA in a plan view. For example, the second input insulating layer IL2 may continuously extend in the first, second, and third light emitting areas PXA_R, PXA_G, and PXA_B and the non-light emitting area NPXA. The second input insulating layer IL2 may include an organic material such as, for example, an acrylic resin, a polyimide resin, or the like or an inorganic material such as, for example, silicon oxide (SiOₓ), silicon nitride (SiNₓ), silicon oxynitride (SiOₓN_{y}), or the like. These may be used alone or in combination with each other.

Although FIG. 3 illustrates that the input sensing layer ISL includes the first conductive layer ICL1, the second conductive layer ICL2, and the second input insulating layer IL2, the present disclosure is not limited thereto. For example, the input sensing layer ISL may further include a base insulating layer disposed between the first conductive layer ICL1 and the encapsulation layer TFE, may include only one of the first and second conductive layers ICL1 and ICL2, or may not include the second input insulating layer IL2.

The color filter layer CFL may be disposed on the input sensing layer ISL. The color filter layer CFL may include a first color filter CF_R, a second color filter CF_G, a third color filter CF_B, a light blocking portion BM, and an overcoating layer OCL. The first, second, and third color filters CF_R, CF_G, and CF_B and the light blocking portion BM may be disposed on the input sensing layer ISL.

The first color filter CF_R may overlap the first light emitting area PXA_R in a plan view. For example, the first color filter CF_R may be disposed to correspond to the first light emitting layer EL1. The first color filter CF_R may transmit the first light LR, and may block light in a wavelength band different from that of the first light LR. For example, the first color filter CF_R may transmit light in a red wavelength band, and may block light in green and blue wavelength bands, but the present disclosure is not limited thereto. Accordingly, in the first light emitting area PXA_R, the first light LR, which is light in the red wavelength band, may be emitted to the outside (e.g., in the third direction DR3).

The second color filter CF_G may overlap the second light emitting area PXA_G in a plan view. For example, the second color filter CF_G may be disposed to correspond to the second light emitting layer EL2. The second color filter CF_G may transmit the second light LG, and may block light in a wavelength band different from that of the second light LG. For example, the second color filter CF_G may transmit light in a green wavelength band, and may block light in red and blue wavelength bands, but the present disclosure is not limited thereto. Accordingly, in the second light emitting area PXA_G, the second light LG, which is light in the green wavelength band, may be emitted to the outside (e.g., in the third direction DR3).

The third color filter CF_B may overlap the third light emitting area PXA_B in a plan view. For example, the third color filter CF_B may be disposed to correspond to the third light emitting layer EL3. The third color filter CF_B may transmit the third light LB, and may block light in a wavelength band different from that of the third light LB. For example, the third color filter CF_B may transmit light in a blue wavelength band, and may block light in red and green wavelength bands, but the present disclosure is not limited thereto. For example, the third color filter CF_B may be a transparent filter including a transparent photosensitive resin. Accordingly, in the third light emitting area PXA_B, the third light LB, which is light in the blue wavelength band, may be emitted to the outside (e.g., in the third direction DR3). For example, the color filter layer CFL may include the first color filter CF_R for transmitting light of a red wavelength region, the second color filter CF_G for transmitting light of a green wavelength region, and the third color filter CF_B for transmitting light of a blue wavelength region. The first, second, and third color filters CF_R, CF_G, and CF_B disposed in the pixels PX can enhance color purity of lights emitted from the emission areas of the respective pixels PX. Accordingly, color filter layer CFL including the first, second, and third color filters CF_R, CF_G, and CF_B may enhance display quality of the display device 10.

The light blocking portion BM may overlap the non-light emitting area NPXA in a plan view. The light blocking portion BM may be disposed between the first, second, and third color filters CF_R, CF_G, and CF_B. In an embodiment of the present disclosure, the light blocking portion BM may include a light blocking material. The light blocking material may include, for example, carbon black, a black dye, a black pigment, a metal, a metal oxide, a metal nitride, or the like. However, this is merely illustrative, and a material of the light blocking portion BM is not particularly limited provided that the material absorbs light. Since the light blocking portion BM includes the light blocking material, reflection of external light due to a lower component may be reduced.

The overcoating layer OCL may be disposed on the first, second, and third color filters CF_R, CF_G, and CF_B and the light blocking portion BM. The overcoating layer OCL may include an organic material such as, for example, an acrylic resin, an epoxy resin, or the like. The overcoating layer OCL may compensate for a step difference between the first, second, and third color filters CF_R, CF_G, and CF_B. The overcoating layer OCL may have a predetermined thickness, and may planarize an upper surface of the color filter layer CFL. The overcoating layer OCL covers and protects the first, second, and third color filters CF_R, CF_G, and CF_B. In an embodiment of the present disclosure, the overcoating layer OCL may also provide a flat top surface.

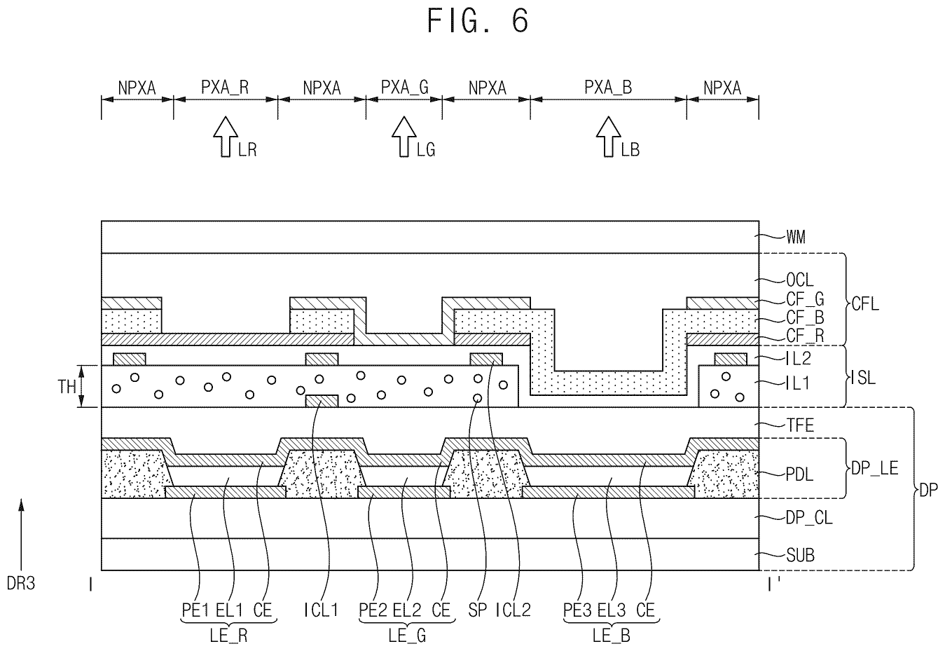

The window WM may be disposed on the color filter layer CFL. The window WM may include an optically transparent material capable of outputting the image. For example, the window WM may include glass or plastic. The window WM may have a single layer structure or a multi-layer structure. For example, the window WM may include a plurality of plastic films bonded by an adhesive, or may include a glass substrate and a plastic film bonded by an adhesive. The window WM may be bonded to the color filter layer CFL by an adhesive layer. The adhesive layer may include, for example, an optically clear adhesive, an optically clear adhesive resin, a pressure sensitive adhesive, or the like. In an embodiment of the present disclosure, the window WM may further include at least one functional layer provided on the window WM. For example, the functional layer may be a hard coating layer, an anti-fingerprint coating layer, an anti-reflective layer, or the like, but the present disclosure is not limited thereto. FIG. 6 is an example of a cross-sectional view taken along line I-I′ of FIG. 2.

The display device 10 described with reference to FIG. 6 may be substantially the same as or similar to the display device 10 described with reference to FIG. 3 except for the color filter layer CFL. In addition, there is no light blocking portion BM in FIG. 6. Hereinafter, redundant descriptions will be omitted or simplified.

Referring to FIG. 6, the display device 10 may include the display panel DP, the input sensing layer ISL, a color filter layer CFL, and the window WM. The display panel DP may include the substrate SUB, the circuit layer DP_CL, the element layer DP_LE, and the encapsulation layer TFE.

The input sensing layer ISL and the color filter layer CFL may be sequentially disposed on the display panel DP. The color filter layer CFL may include a first color filter CF_R, a second color filter CF_G, a third color filter CF_B, and an overcoating layer OCL. The first, second, and third color filters CF_R, CF_G, and CF_B may be disposed on the input sensing layer ISL.

The first color filter CF_R may overlap the first light emitting area PXA_R in a plan view. For example, the first color filter CF_R may be disposed to correspond to the first light emitting layer EL1. The first color filter CF_R may transmit the first light LR, and may block light in a wavelength band different from that of the first light LR. Accordingly, in the first light emitting area PXA_R, the first light LR, which is light in the red wavelength band, may be emitted to the outside (e.g., in the third direction DR3).

The second color filter CF_G may overlap the second light emitting area PXA_G in a plan view. For example, the second color filter CF_G may be disposed to correspond to the second light emitting layer EL2. The second color filter CF_G may transmit the second light LG, and may block light in a wavelength band different from that of the second light LG. Accordingly, in the second light emitting area PXA_G, the second light LG, which is light in the green wavelength band, may be emitted to the outside (e.g., in the third direction DR3).

The third color filter CF_B may overlap the third light emitting area PXA_B in a plan view. For example, the third color filter CF_B may be disposed to correspond to the third light emitting layer EL3. The third color filter CF_B may transmit the third light LB, and may block light in a wavelength band different from that of the third light LB. Alternatively, the third color filter CF_B may be a transparent filter. Accordingly, in the third light emitting area PXA_B, the third light LB, which is light in the blue wavelength band, may be emitted to the outside (e.g., in the third direction DR3).

In an embodiment of the present disclosure, each of the first color filter CF_R, the second color filter CF_G, and the third color filter CF_B may overlap the non-light emitting area NPXA in a plan view. For example, in a plan view, the first color filter CF_R may overlap the first light-emitting area PXA_R and the non-light emitting area NPXA, and may not overlap the second and third light-emitting areas PXA_G and PXA_B. In a plan view, the second color filter CF_G may overlap the second light-emitting area PXA_G and the non-light emitting area NPXA, and may not overlap the first and third light-emitting areas PXA_R and PXA_B. In a plan view, the third color filter CF_B may overlap the third light-emitting area PXA_B and the non-light emitting area NPXA, and may not overlap the first and second light-emitting areas PXA_R and PXA_G.

In this case, in the non-light emitting area NPXA, the first, second, and third color filters CF_R, CF_G, and CF_B may overlap each other in the third direction DR3. For example, in the non-light emitting area NPXA, the third color filter CF_B may be disposed on the first color filter CF_R, and the second color filter CF_G may be disposed on the third color filter CF_B. Accordingly, color mixing between the first, second, and third light emitting areas PXA_R, PXA_G, and PXA_B may be prevented. In FIG. 6, in the non-light emitting area NPXA, the first, second, and third color filters CF_R, CF_G, and CF_B overlapping each other in the third direction DR3 may function as a light blocking portion similar to the light blocking portion BM of FIG. 3 to reduce reflection of external light from a lower component.

The overcoating layer OCL may be disposed on the first, second, and third color filters CF_R, CF_G, and CF_B, and the window WM may be disposed on the color filter layer CFL.

The input sensing layer ISL of the display device 10 according to an embodiment of the present disclosure may include the first input insulating layer IL1 including the scattering particles SP disposed between the first conductive layer ICL1 and the second conductive layer ICL2 to scatter light that is reflected from a lower component. Since the scatting particles SP effectively scatter light incident on the first input insulating layer IL1, a color band phenomenon due to reflection of external light may be prevented or minimized. In addition, since the first input insulating layer IL1 including the scattering particles SP overlaps the first and second light emitting areas PXA_R and PXA_G in a plan view, and does not overlap the third light emitting area PXA_B in a plan view, a decrease in light extraction efficiency of the display device 10 may be minimized. Accordingly, display quality of the display device 10 may be enhanced.

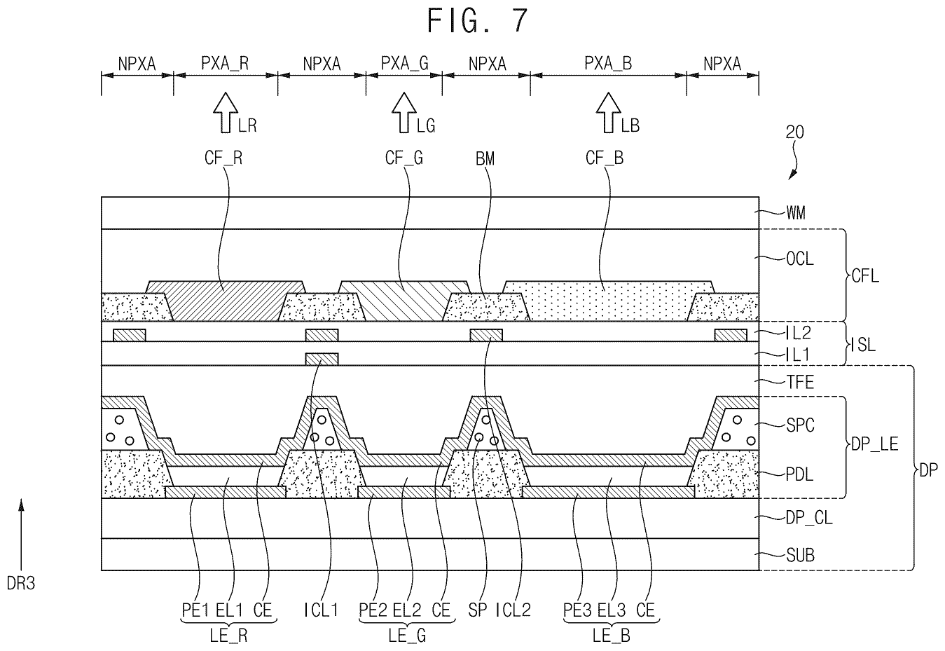

FIG. 7 is a cross-sectional view illustrating a display device according to an embodiment of the present disclosure. For example, FIG. 7 may correspond to the cross-sectional view of FIG. 3.

Hereinafter, descriptions overlapping the display device 10 described with reference to FIGS. 1, 2, 3, 4, 5, and 6 will be omitted or simplified.

Referring to FIG. 7, a display device 20 may include a display panel DP, an input sensing layer ISL, a color filter layer CFL, and a window WM. The display panel DP may include a substrate SUB, a circuit layer DP_CL, an element layer DP_LE, and an encapsulation layer TFE.

The circuit layer DP_CL and the element layer DP_LE may be sequentially disposed on the substrate SUB. The element layer DP_LE may include a first light emitting element LE_R, a second light emitting element LE_G, a third light emitting element LE_B, a pixel defining layer PDL, and a spacer SPC.

Here, the first light emitting element LE_R may include a first pixel electrode PE1, a first light emitting layer EL1, and a common electrode CE, the second light emitting element LE_G may include a second pixel electrode PE2, a second light emitting layer EL2, and the common electrode CE, and the third light emitting element LE_B may include a third pixel electrode PE3, a third light emitting layer EL3, and the common electrode CE. The common electrode CE may be disposed to cover the pixel defining layer PDL, the spacer SPC, and the first, second, and third light emitting layers EL1, EL2, and EL3.

The first, second, and third pixel electrodes PE1, PE2, and PE3 may be disposed on the circuit layer DP_CL. The first, second, and third pixel electrodes PE1, PE2, and PE3 may overlap first, second, and third light emitting areas PXA_R, PXA_G, and PXA_B, respectively, in a plan view.

The pixel defining layer PDL may be disposed on the circuit layer DP_CL. The pixel defining layer PDL may expose at least a portion of an upper surface of each of the first, second, and third pixel electrodes PE1, PE2, and PE3. For example, the pixel defining layer PDL may cover a side surface of each of the first, second, and third pixel electrodes PE1, PE2, and PE3, and may expose a central portion of each of the first, second, and third pixel electrodes PE1, PE2, and PE3. The pixel defining layer PDL may overlap the non-light emitting area NPXA in a plan view. The first, second, and third light emitting areas PXA_R, PXA_G, and PXA_B may be defined respectively corresponding to areas of the first, second, and third pixel electrodes PE1, PE2, and PE3 exposed by the pixel defining layer PDL on the substrate SUB. The non-light emitting area NPXA may be defined between the first, second, and third light emitting areas PXA_R, PXA_G, and PXA_B on the substrate SUB. In an embodiment of the present disclosure, the pixel defining layer PDL may include a light blocking material. For example, the pixel defining layer PDL may include an organic light-shielding material or inorganic light-shielding material including a black pigment and/or a black dye. In addition, the pixel defining layer PDL may implement a black pixel defining layer.

The spacer SPC may be disposed on the pixel defining layer PDL. The spacer SPC may overlap the non-light emitting area NPXA in a plan view. For example, a thickness of the spacer SPC may be greater than or equal to about 1.0 μm and smaller than or equal to about 1.5 μm, but the present disclosure is not limited thereto.

In an embodiment of the present disclosure, the spacer SPC may include scattering particles SP. The scattering particles SP may be dispersed and positioned within the spacer SPC. For example, the scattering particles SP may include, for example, titanium oxide (TiO₂), zinc oxide (ZnO), zirconium oxide (ZrO₂), aluminum oxide (Al₂O₃), cerium oxide (CeO₂), silicon oxide (SiO₂), or the like.

The scattering particle SP may be, for example, spherical, elliptical, or amorphous. In an embodiment of the present disclosure, an average diameter of the scattering particles SP may be greater than or equal to about 50 nm and smaller than or equal to about 500 nm. For example, the average diameter of the scattering particles SP may be an arithmetic average of a cross-sectional diameter D of each of a plurality of scattering particles SP (see FIG. 5). The scattering particles SP may scatter light that is reflected from the spacer SPC and travels to the outside, thereby preventing a color band due to reflection from being visually recognized or minimizing a degree to which it is visually recognized.

In an embodiment of the present disclosure, a content of the scattering particles SP included in the spacer SPC may be greater than or equal to about 5 wt % and less than or equal to about 50 wt % based on a total weight of the spacer SPC. If the content of the scattering particles SP is less than about 5 wt %, reflected light scattering may be relatively insufficient, and if the content of the scattering particles SP is greater than about 50 wt %, it may be relatively difficult to manufacture the spacer SPC.

The first, second, and third light emitting layers EL1, EL2, and EL3 may be disposed on the first, second, and third pixel electrodes PE1, PE2, and PE3 exposed by the pixel defining layer PDL, respectively. The first, second, and third light emitting layers EL1, EL2, and EL3 may overlap the first, second, and third light emitting areas PXA_R, PXA_G, and PXA_B, respectively, in a plan view.

The first light emitting layer EL1 may emit first light LR, and may include an organic material that emits the first light LR. The second light emitting layer EL2 may emit second light LG, and may include an organic material that emits the second light LG. The third light emitting layer EL3 may emit third light LB, and may include an organic material that emits the third light LB. For example, the first light LR may be light in a red wavelength band, the second light LG may be light in a green wavelength band, and the third light LB may be light in a blue wavelength band, but the present disclosure is not limited thereto. In an embodiment of the present disclosure, each of the first, second, and third light emitting layers EL1, EL2, and EL3 may include one or both of an organic light emitting material and a quantum dot. For example, each of the first, second, and third light emitting layers EL1, EL2, and EL3 may include an organic material including a fluorescent or phosphorescent material that emits red, green, and blue light, respectively, or emits white light. The quantum dot may include a fluorescent material or a phosphorescent material, and may produce monochromatic red, green, and blue light.

The common electrode CE may be disposed on the pixel defining layer PDL, the spacer SPC, and the first, second, and third light emitting layers EL1, EL2, and EL3. The common electrode CE may overlap the first, second, and third light emitting areas PXA_R, PXA_G, and PXA_B and the non-light emitting area NPXA in a plan view. For example, the common electrode CE may continuously extend in the first, second, and third light emitting areas PXA_R, PXA_G, and PXA_B and the non-light emitting area NPXA.

The encapsulation layer TFE and the input sensing layer ISL may be sequentially disposed on the common electrode CE. For example, the input sensing layer ISL may be directly disposed on the encapsulation layer TFE. Since the common electrode CE may be disposed on the pixel defining layer PDL and the spacer SPC, the pixel defining layer PDL may be disposed between the substrate SUB and the input sensing layer ISL, and the spacer SPC may be disposed on the pixel defining layer PDL. The input sensing layer ISL may include a first conductive layer ICL1, a first input insulating layer IL1, a second conductive layer ICL2, and a second input insulating layer IL2.

The first conductive layer ICL1, the first input insulating layer IL1, the second conductive layer ICL2, and the second input insulating layer IL2 may be sequentially disposed on the encapsulation layer TFE.

Each of the first and second conductive layers ICL1 and ICL2 may overlap the non-light emitting area NPXA in a plan view. The first and second input insulating layers IL1 and IL2 may cover the first and second conductive layers ICL1 and ICL2, respectively. Each of the first and second input insulating layers IL1 and IL2 may overlap the first, second, and third light emitting areas PXA_R, PXA_G, and PXA_B and the non-light emitting area NPXA in a plan view. For example, each of the first and second input insulating layers IL1 and IL2 may continuously extend in the first, second, and third light emitting areas PXA_R, PXA_G, and

PXA_B and the non-light emitting area NPXA. Different from the first input insulating layer IL1 shown in FIG, 3, the first input insulating layer IL1 shown in FIG. 7 does not include the scattering particles SP, and is overlapped with the third light emitting area PXA_B in a plan view. Each of the first and second input insulating layers IL1 and IL2 may include an organic material such as, for example, an acrylic resin, a polyimide resin, or the like or an inorganic material such as, for example, silicon oxide (SiOₓ), silicon nitride (SiNₓ), silicon oxynitride (SiOₓN_{y}), or the like. These may be used alone or in combination with each other.

Although FIG. 7 illustrates that the input sensing layer ISL includes the first conductive layer ICL1, the second conductive layer ICL2, and the second input insulating layer IL2, the present disclosure is not limited thereto. For example, the input sensing layer ISL may further include a base insulating layer disposed between the first conductive layer ICL1 and the encapsulation layer TFE, may include only one of the first and second conductive layers ICL1 and ICL2, or may not include the second input insulating layer IL2.

The color filter layer CFL may be disposed on the input sensing layer ISL. The color filter layer CFL may include a first color filter CF_R, a second color filter CF_G, a third color filter CF_B, a light blocking portion BM, and an overcoating layer OCL.

The first, second, and third color filters CF_R, CF_G, and CF_B and the light blocking portion BM may be disposed on the input sensing layer ISL. The light blocking portion BM may be disposed between the first, second, and third color filters CF_R, CF_G, and CF_B. In a plan view, the first, second, and third color filters CF_R, CF_G, and CF_B may overlap the first, second, and third light emitting areas PXA_R, PXA_G, and PXA_B, respectively, and the light blocking portion BM may overlap the non-light emitting area NPXA.

The first color filter CF_R may transmit the first light LR, and may block light in a wavelength band different from that of the first light LR. Accordingly, in the first light emitting area PXA_R, the first light LR, which is light in the red wavelength band, may be emitted to the outside (e.g., in a third direction DR3). The second color filter CF_G may transmit the second light LG, and may block light in a wavelength band different from that of the second light LG. Accordingly, in the second light emitting area PXA_G, the second light LG, which is light in the green wavelength band, may be emitted to the outside (e.g., in the third direction DR3). The third color filter CF_B may transmit the third light LB, and may block light in a wavelength band different from that of the third light LB. Alternatively, the third color filter CF_B may be a transparent filter. Accordingly, in the third light emitting area PXA_B, the third light LB, which is light in the red wavelength band, may be emitted to the outside (e.g., in the third direction DR3). The first, second, and third color filters CF_R, CF_G, and CF_B disposed in the pixels PX can enhance color purity of lights emitted from the first, second, and third light emitting areas PXA_R, PXA_G, and PXA_B. Accordingly, color filter layer CFL including the first, second, and third color filters CF_R, CF_G, and CF_B may enhance display quality of the display device 20.

The overcoating layer OCL may be disposed on the first, second, and third color filters CF_R, CF_G, and CF_B and the light blocking portion BM. The window WM may be disposed on the color filter layer CFL.

Although FIG. 7 illustrates that the color filter layer CFL includes the first, second, and third color filters CF_R, CF_G, and CF_B and the light blocking portion BM, the present disclosure is not limited thereto. For example, the color filter layer CFL may not include the light blocking portion BM, each of the first, second, and third color filters CF_R, CF_G, and CF_B may further overlap the non-light emitting area NPXA in a plan view, and the first, second, and third color filters CF_R, CF_G, and CF_B may overlap each other in the third direction DR3 in the non-light emitting area NPXA. In this case, in the non-light emitting area NPXA, the first, second, and third color filters CF_R, CF_G, and CF_B overlapping each other in the third direction DR3 may function as the light blocking portion BM to reduce reflection of external light from a lower component.

The display device 20 according to an embodiment of the present disclosure may include the spacer SPC disposed on the pixel defining layer PDL and including the scattering particles SP. Since the scattering particles SP scatter light incident on the spacer SPC, a color band phenomenon due to reflection of external light may be prevented or minimized. In addition, since the spacer SPC overlaps the non-light emitting area NPXA in a plan view, a decrease in light extraction efficiency of the display device 20 may be minimized. Accordingly, display quality of the display device 20 may be enhanced.

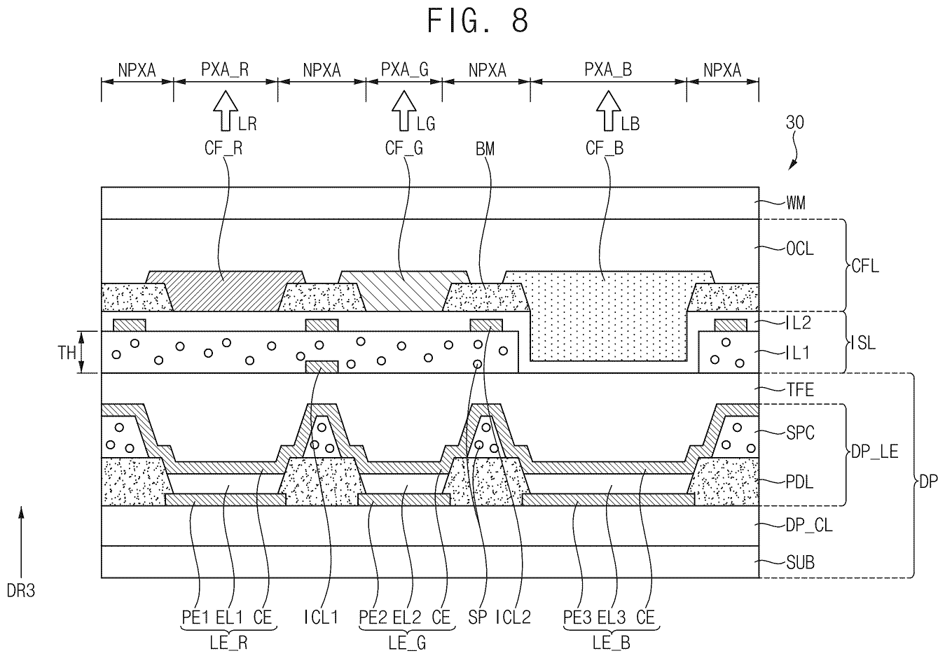

FIG. 8 is a cross-sectional view illustrating a display device according to an embodiment of the present disclosure. For example, FIG. 8 may correspond to the cross-sectional view of FIG. 3.

Hereinafter, descriptions overlapping the display device 10 described with reference to FIGS. 1, 2, 3, 4, 5, and 6 will be omitted or simplified.

Referring to FIG. 8, a display device 30 may include a display panel DP, an input sensing layer ISL, a color filter layer CFL, and a window WM. The display panel DP may include a substrate SUB, a circuit layer DP_CL, an element layer DP_LE, and an encapsulation layer TFE.

The circuit layer DP_CL and the element layer DP_LE may be sequentially disposed on the substrate SUB. The element layer DP_LE may include a first light emitting element LE_R, a second light emitting element LE_G, a third light emitting element LE_B, a pixel defining layer PDL, and a spacer SPC.

Here, the first light emitting element LE_R may include a first pixel electrode PE1, a first light emitting layer EL1, and a common electrode CE, the second light emitting element LE_G may include a second pixel electrode PE2, a second light emitting layer EL2, and the common electrode CE, and the third light emitting element LE_B may include a third pixel electrode PE3, a third light emitting layer EL3, and the common electrode CE. The common electrode CE may be disposed to cover the pixel defining layer PDL, the spacer SPC, and the first, second, and third light emitting layers EL1, EL2, and EL3.

The first, second, and third pixel electrodes PE1, PE2, and PE3 may be disposed on the circuit layer DP_CL. The first, second, and third pixel electrodes PE1, PE2, and PE3 may overlap the first, second, and third light emitting areas PXA_R, PXA_G, and PXA_B, respectively, in a plan view.

The pixel defining layer PDL may be disposed on the circuit layer DP_CL. The pixel defining layer PDL may expose at least a portion of an upper surface of each of the first, second, and third pixel electrodes PE1, PE2, and PE3. For example, the pixel defining layer PDL may cover a side surface of each of the first, second, and third pixel electrodes PE1, PE2, and PE3, and may expose a central portion of each of the first, second, and third pixel electrodes PE1, PE2, and PE3. The pixel defining layer PDL may overlap the non-light emitting area NPXA in a plan view. The first, second, and third light emitting areas PXA_R, PXA_G, and PXA_B may be defined respectively corresponding to areas of the first, second, and third pixel electrodes PE1, PE2, and PE3 exposed by the pixel defining layer PDL on the substrate SUB. The non-light emitting area NPXA may be defined between the first, second, and third light emitting areas PXA_R, PXA_G, and PXA_B on the substrate SUB. In an embodiment of the present disclosure, the pixel defining layer PDL may include a light blocking material. For example, the pixel defining layer PDL may include an organic light-shielding material or inorganic light-shielding material including a black pigment and/or a black dye. In addition, the pixel defining layer PDL may implement a black pixel defining layer.

The spacer SPC may be disposed on the pixel defining layer PDL. The spacer SPC may overlap the non-light emitting area NPXA in a plan view. For example, a thickness of the spacer SPC may be greater than or equal to about 1.0 μm and smaller than or equal to about 1.5 μm, but the present disclosure is not limited thereto.

In an embodiment of the present disclosure, the spacer SPC may include scattering particles SP. The scattering particles SP may be dispersed and positioned within the spacer SPC. For example, the scattering particles SP may include, for example, titanium oxide (TiO₂), zinc oxide (ZnO), zirconium oxide (ZrO₂), aluminum oxide (Al₂O₃), cerium oxide (CeO₂), silicon oxide (SiO₂), or the like.

The scattering particle SP may be, for example, spherical, elliptical, or amorphous. In an embodiment of the present disclosure, an average diameter of the scattering particles SP may be greater than or equal to about 50 nm and smaller than or equal to about 500 nm. For example, the average diameter of the scattering particles SP may be an arithmetic average of a cross-sectional diameter D of each of a plurality of scattering particles SP (see FIG. 5). In an embodiment of the present disclosure, a content of the scattering particles SP included in the spacer SPC may be greater than or equal to about 5 wt % and less than or equal to about 50 wt % based on a total weight of the spacer SPC. The scattering particles SP may scatter light that is reflected from the spacer SPC and travels to the outside, thereby preventing a color band due to reflection from being visually recognized or minimizing a degree to which it is visually recognized.

The first, second, and third light emitting layers EL1, EL2, and EL3 may be disposed on the first, second, and third pixel electrodes PE1, PE2, and PE3 exposed by the pixel defining layer PDL, respectively. The first, second, and third light emitting layers EL1, EL2, and EL3 may overlap the first, second, and third light emitting areas PXA_R, PXA_G, and PXA_B, respectively, in a plan view.

The first light emitting layer EL1 may emit first light LR, and may include an organic material that emits the first light LR. The second light emitting layer EL2 may emit second light LG, and may include an organic material that emits the second light LG. The third light emitting layer EL3 may emit third light LB, and may include an organic material that emits the third light LB. For example, the first light LR may be light in a red wavelength band, the second light LG may be light in a green wavelength band, and the third light LB may be light in a blue wavelength band, but the present disclosure is not limited thereto. In an embodiment of the present disclosure, each of the first, second, and third light emitting layers EL1, EL2, and EL3 may include one or both of an organic light emitting material and a quantum dot. For example, each of the first, second, and third light emitting layers EL1, EL2, and EL3 may include an organic material including a fluorescent or phosphorescent material that emits red, green, and blue light, respectively, or emits white light. The quantum dot may include a fluorescent material or a phosphorescent material, and may produce monochromatic red, green, and blue light.

The common electrode CE may be disposed on the pixel defining layer PDL, the spacer SPC, and the first, second, and third light emitting layers EL1, EL2, and EL3. The common electrode CE may overlap the first, second, and third light emitting areas PXA_R, PXA_G, and PXA_B and the non-light emitting area NPXA in a plan view. For example, the common electrode CE may continuously extend in the first, second, and third light emitting areas PXA_R, PXA_G, and PXA_B and the non-light emitting area NPXA.

The encapsulation layer TFE and the input sensing layer ISL may be sequentially disposed on the common electrode CE. For example, the input sensing layer ISL may be directly disposed on the encapsulation layer TFE. The input sensing layer ISL may include a first conductive layer ICL1, a first input insulating layer IL1, a second conductive layer ICL2, and a second input insulating layer IL2.

The first conductive layer ICL1 may be disposed on the encapsulation layer TFE, and may overlap the non-light emitting area NPXA in a plan view. The first input insulating layer IL1 may be disposed on the first conductive layer ICL1, and may cover the first conductive layer ICL1.

In an embodiment of the present disclosure, in a plan view, the first input insulating layer IL1 may overlap the first light emitting area PXA_R and the second light emitting area PXA_G, and may not overlap the third light emitting area PXA_B. In addition, the first input insulating layer IL1 may overlap the non-light emitting area NPXA in a plan view. The first input insulating layer IL1 may include an organic material such as, for example, an acrylic resin, a polyimide resin, or the like. The first input insulating layer IL1 may be formed not to overlap the third light emitting area PXA_B in a plan view through a photolithography process. The first input insulating layer IL1 having a relatively thick thickness is required to be formed to cover the first conductive layer ICL1. For example, a thickness TH of the first input insulating layer IL1 may be greater than or equal to about 1.0 μm and smaller than or equal to about 1.8 μm, but the present disclosure is not limited thereto. The first input insulating layer IL1 may provide a flat top surface on the encapsulation layer TFE.

In an embodiment of the present disclosure, the first input insulating layer IL1 may include the scattering particles SP. The scattering particles SP may be dispersed and positioned within the first input insulating layer IL1. In an embodiment of the present disclosure, the average diameter of the scattering particles SP may be greater than or equal to about 50 nm and smaller than or equal to about 500 nm. In an embodiment of the present disclosure, a content of the scattering particles SP included in the first input insulating layer IL1 may be greater than or equal to 0 wt % and less than or equal to about 10 wt % based on a total weight of the first input insulating layer IL1. For example, a content of the scattering particles SP included in the first input insulating layer IL1 may be greater than 0 wt %, but not greater than about 10 wt %. A haze of the first input insulating layer IL1 may be greater than or equal to about 10% and less than or equal to about 50%.

The scattering particles SP may scatter light that is reflected from a lower component and travels to the outside, thereby preventing a color band due to reflection from being visually recognized or minimizing a degree to which it is visually recognized. In addition, the scattering particles SP may be disposed not to overlap the third light emitting area PXA_B that emits the third light LB in a plan view, thereby minimizing a decrease in light extraction efficiency of the display device 30. For example, the light extraction efficiency of the blue pixel PX will not be reduced or be minimally reduced, when the scattering particles SP are located in the first and second light emitting areas PXA_R and PXA_G corresponding to the red pixel PX and green pixel PX, but not located in the third light emitting area PXA_B corresponding to the blue pixel PX. Accordingly, display quality of the display device 30 may be enhanced.

The second conductive layer ICL2 may be disposed on the first input insulating layer IL1, and may overlap the non-light emitting area NPXA in a plan view. The second input insulating layer IL2 may be disposed on the first input insulating layer IL1 and the second conductive layer ICL2, and may cover the first input insulating layer IL1 and the second conductive layer ICL2. The second input insulating layer IL2 may prevent the second conductive layer ICL2 from contacting the color filter layer CFL. Accordingly, a material (e.g., organic layer) that forms the color filter layer CFL may be prevented from damaging the second conductive layer ICL2. The second input insulating layer IL2 may overlap the first, second, and third light emitting areas PXA_R, PXA_G, and PXA_B and the non-light emitting area NPXA in a plan view. The second input insulating layer IL2 may include an organic material such as, for example, an acrylic resin, a polyimide resin, or the like or an inorganic material such as, for example, silicon oxide (SiOₓ), silicon nitride (SiNₓ), silicon oxynitride (SiOₓN_{y}), or the like. These may be used alone or in combination with each other.

Although FIG. 8 illustrates that the input sensing layer ISL includes the first conductive layer ICL1, the second conductive layer ICL2, and the second input insulating layer IL2, the present disclosure is not limited thereto. For example, the input sensing layer ISL may further include a base insulating layer disposed between the first conductive layer ICL1 and the encapsulation layer TFE, may include only one of the first and second conductive layers ICL1 and ICL2, or may not include the second input insulating layer IL2.

The color filter layer CFL may be disposed on the input sensing layer ISL. The color filter layer CFL may include a first color filter CF_R, a second color filter CF_G, a third color filter CF_B, a light blocking portion BM, and an overcoating layer OCL.

Since the input sensing layer ISL may be directly disposed on the encapsulation layer TFE and the encapsulation layer TFE may be disposed on the common electrode CE which may be disposed on the first, second, and third light emitting layers EL1, EL2, and EL3, a light emitting layer including the first, second, and third light emitting layers EL1, EL2, and EL3 may be disposed between the substrate SUB and the input sensing layer ISL. Also, since the color filter layer CFL may be disposed on the input sensing layer ISL, the light emitting layer including the first, second, and third light emitting layers EL1, EL2, and EL3 may be disposed between the substrate SUB and the color filter layer CFL.

The first, second, and third color filters CF_R, CF_G, and CF_B and the light blocking portion BM may be disposed on the input sensing layer ISL. The light blocking portion BM may be disposed between the first, second, and third color filters CF_R, CF_G, and CF_B. In a plan view, the first, second, and third color filters CF_R, CF_G, and CF_B may overlap the first, second, and third light emitting areas PXA_R, PXA_G, and PXA_B, respectively, and the light blocking portion BM may overlap the non-light emitting area NPXA.

The first color filter CF_R may transmit the first light LR, and may block light in a wavelength band different from that of the first light LR. Accordingly, in the first light emitting area PXA_R, the first light LR, which is light in the red wavelength band, may be emitted to the outside (e.g., in a third direction DR3). The second color filter CF_G may transmit the second light LG, and may block light in a wavelength band different from that of the second light LG. Accordingly, in the second light emitting area PXA_G, the second light LG, which is light in the green wavelength band, may be emitted to the outside (e.g., in the third direction DR3). The third color filter CF_B may transmit the third light LB, and may block light in a wavelength band different from that of the third light LB. Alternatively, the third color filter CF_B may be a transparent filter. Accordingly, in the third light emitting area PXA_B, the third light LB, which is light in the blue wavelength band, may be emitted to the outside (e.g., in the third direction DR3). The first, second, and third color filters CF_R, CF_G, and CF_B disposed in the pixels PX can enhance color purity of lights emitted from the first, second, and third light emitting areas PXA_R, PXA_G, and PXA_B. Accordingly, color filter layer CFL including the first, second, and third color filters CF_R, CF_G, and CF_B may enhance display quality of the display device 30.

The overcoating layer OCL may be disposed on the first, second, and third color filters CF_R, CF_G, and CF_B and the light blocking portion BM. The window WM may be disposed on the color filter layer CFL.

Although FIG. 8 illustrates that the color filter layer CFL includes the first, second, and third color filters CF_R, CF_G, and CF_B and the light blocking portion BM, the present disclosure is not limited thereto. For example, the color filter layer CFL may not include the light blocking portion BM, each of the first, second, and third color filters CF_R, CF_G and CF_B may further overlap the non-light emitting area NPXA in a plan view, and the first, second, and third color filters CF_R, CF_G, and CF_B may overlap each other in the third direction DR3 in the non-light emitting area NPXA. In this case, in the non-light emitting area NPXA, the first, second, and third color filters CF_R, CF_G, and CF_B overlapping each other in the third direction DR3 may function as the light blocking portion BM to reduce reflection of external light from a lower component.

The display device 30 according to an embodiment of the present disclosure may include the input sensing layer ISL including the first input insulating layer IL1 including the scattering particles SP and the spacer SPC disposed on the pixel defining layer PDL and including the scattering particles SP. Since the scattering particles SP scatter light incident on each of the first input insulating layer IL1 and the spacer SPC, a color band phenomenon due to reflection of external light may be prevented or minimized. In addition, since the first input insulating layer IL1 does not overlap the third light emitting area PXA_B in a plan view, and the spacer SPC overlaps the non-light emitting area NPXA in a plan view, a decrease in light extraction efficiency of the display device 30 may be minimized. Accordingly, display quality of the display device 30 may be enhanced.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments of the present disclosure and is not to be construed as limiting thereof. Although a few specific embodiments have been described, those skilled in the art will readily appreciate that many modifications are possible in the specific embodiments without materially departing from the teachings of the present disclosure. Accordingly, all such modifications are intended to be included within the scope of the present disclosure as defined in the appended claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the present disclosure.

What is claimed is:

1. A display device comprising:
a first light emitting area that emits first light, a second light emitting area that emits second light, and a third light emitting area that emits third light respectively defined on a substrate;
an input sensing layer disposed on the substrate and including a first input insulating layer, the first input insulating layer overlapping the first light emitting area and the second light emitting area in a plan view and including scattering particles; and
a color filter layer disposed on the input sensing layer.

2. The display device of claim 1, wherein the first input insulating layer does not overlap the third light emitting area in a plan view.

3. The display device of claim 1, wherein
the first light is light in a red wavelength band,
the second light is light in a green wavelength band, and
the third light is light in a blue wavelength band.

4. The display device of claim 1, wherein the first input insulating layer includes an organic material.

5. The display device of claim 1, wherein an average diameter of the scattering particles is greater than or equal to about 50 nm and smaller than or equal to about 500 nm.

6. The display device of claim 1, wherein a content of the scattering particles included in the first input insulating layer is greater than 0 wt % and less than or equal to about 10 wt % based on a total weight of the first input insulating layer.

7. The display device of claim 1, wherein a thickness of the first input insulating layer is greater than or equal to about 1.0 μm and smaller than or equal to about 1.8 μm.

8. The display device of claim 1, wherein the input sensing layer further includes:
a second input insulating layer disposed on the first input insulating layer and covering the first input insulating layer.

9. The display device of claim 8, wherein the second input insulating layer continuously extends in the first light emitting area, the second light emitting area, and the third light emitting area.

10. The display device of claim 1, wherein the color filter layer includes:
a first color filter overlapping the first light emitting area in a plan view;
a second color filter overlapping the second light emitting area in a plan view; and
a third color filter overlapping the third light emitting area in a plan view.

11. The display device of claim 10, wherein the color filter layer further includes:
a light blocking portion disposed between the first color filter, the second color filter, and the third color filter.

12. The display device of claim 1, wherein a haze of the first input insulating layer is greater than or equal to about 10% and less than or equal to about 50%.

13. The display device of claim 1, further comprising:
a pixel defining layer disposed between the substrate and the input sensing layer; and
a spacer disposed on the pixel defining layer.

14. The display device of claim 13, wherein the spacer includes the scattering particles.

15. The display device of claim 14, wherein a content of the scattering particles included in the spacer is greater than or equal to about 5 wt % and less than or equal to about 50 wt % based on a total weight of the spacer.

16. The display device of claim 1, further comprising:
a light emitting layer disposed between the substrate and the input sensing layer,
wherein the light emitting layer includes:
a first light emitting layer overlapping the first light emitting area in a plan view and emitting the first light;
a second light emitting layer overlapping the second light emitting area in a plan view and emitting the second light; and
a third light emitting layer overlapping the third light emitting area and emitting the third light.

17. A display device comprising:
a light emitting area and a non-light emitting area surrounding the light emitting area respectively defined on a substrate;
a pixel defining layer disposed on the substrate and overlapping the non-light emitting area in a plan view;
a spacer disposed on the pixel defining layer, overlapping the non-light emitting area in a plan view, and including scattering particles in a content of greater than or equal to about 5 wt % and less than or equal to about 50 wt % based on a total weight of the spacer; and
a color filter layer disposed on the spacer.

18. The display device of claim 17, wherein an average diameter of the scattering particles is greater than or equal to about 50 nm and smaller than or equal to about 500 nm.

19. The display device of claim 17, further comprising:
an input sensing layer disposed between the spacer and the color filter layer.

20. The display device of claim 17, wherein
the light emitting area includes:
a first light emitting area that emits first light;
a second light emitting area that emits second light; and
a third light emitting area that emits third light, and the color filter layer includes:
a first color filter overlapping the first light emitting area in a plan view;
a second color filter overlapping the second light emitting area in a plan view; and
a third color filter overlapping the third light emitting area in a plan view.

21. The display device of claim 20, wherein the color filter layer further includes:
a light blocking portion overlapping the non-light emitting area in a plan view.

22. The display device of claim 20, wherein
the first light is light in a red wavelength band,
the second light is light in a green wavelength band, and
the third light is light in a blue wavelength band.

23. The display device of claim 20, further comprising:
a light emitting layer disposed between the substrate and the color filter layer,
wherein the light emitting layer includes:
a first light emitting layer overlapping the first light emitting area in a plan view and emitting the first light;
a second light emitting layer overlapping the second light emitting area in a plan view and emitting the second light; and
a third light emitting layer overlapping the third light emitting area in a plan view and that emitting the third light.

24. A display device comprising:
a display panel, an input sensing layer, and a color filter layer sequentially disposed on a substrate,
wherein the display panel includes a first light emitting area that emits red light, a second light emitting area that emits green light, and a third light emitting area that emits blue light,
the input sensing layer includes a first conductive layer, a first input insulating layer disposed on and covering the first conductive layer, a second conductive layer disposed on the first input insulating layer, and a second input insulating layer disposed on and covering the second conductive layer and the first input insulating layer, and
the first input insulating layer includes scattering particles and does not overlap the third light emitting area in a plan view.
